(19) United States
(12) Patent Application Publication
(10) Pub. No.: US 2026/0194833 A1
(43) Pub. Date: Jul. 9, 2026

(54) PHOTORESIST SUPPLY SYSTEM

(71) Applicant: Samsung Electronics Co., Ltd., Suwon-si (KR)

(72) Inventors: Beoung-Hun MO, Suwon-si (KR); Woo Chang CHOE, Suwon-si (KR)

(21) Appl. No.: 19/239,765

(22) Filed: Jun. 16, 2025

(30) Foreign Application Priority Data
Jan. 9, 2025 (KR) 10-2025-0003317

(51) Int. Cl. G03F 7/00; G03F 7/16

(52) U.S. Cl. CPC G03F 7/70991; G03F 7/16; G03F 7/70858

(57) ABSTRACT

A photoresist supply system includes a photoresist supply unit in which a photoresist container having an inlet at its top is stored; a photoresist supply device including a buffer tank having an inlet at its top; and a pipeline connecting the inlet of the photoresist container and the inlet of the buffer tank, wherein the photoresist supply unit is positioned above the photoresist supply device.

### CROSS-REFERENCE TO RELATED APPLICATION

This application claims priority under 35 U.S.C. § 119 from Korean Patent Application No. 10-2025-0003317, filed on Jan. 9, 2025, in the Korean Intellectual Property Office, and all the benefits accruing therefrom under 35 U.S.C. 119, the contents of which in its entirety are herein incorporated by reference.

### BACKGROUND

### 1. Field

The present disclosure relates to a photoresist supply system.

### 2. Description of the Related Art

Generally, a semiconductor device can be manufactured by repeatedly performing various processes such as photolithography, etching, deposition, diffusion, and ion implantation using a wafer.

In the photolithography process, a spinner facility is used to apply photoresist onto a wafer. Photoresist is typically stored in bottle-type containers, which are transported and mounted on a photoresist supply facility. Through a supply device extending from the bottle-type containers mounted on the photoresist supply facility to the photoresist nozzle of a spin coater, photoresist is applied onto the wafer. This series of processes, including transporting the bottle-type containers and mounting them on the photoresist supply facility, is traditionally performed by operators. In this case, there is a risk of operator injury due to photoresist leakage and the like.

### SUMMARY

An objective of the present disclosure is to provide a photoresist supply system that retrieves and supplies photoresist containers using an overhead hoist transport (OHT) and supplies photoresist using a siphon effect.

The objectives of the present disclosure are not limited to those mentioned above, and other objectives not explicitly stated will be clearly understood by those skilled in the art based on the following description.

According to an aspect of the present disclosure, there is provided a photoresist supply system including a photoresist supply unit in which a photoresist container having an inlet at its top is stored; a photoresist supply device including a buffer tank having an inlet at its top; and a pipeline connecting the inlet of the photoresist container and the inlet of the buffer tank, wherein the photoresist supply unit is positioned above the photoresist supply device.

According to the aforementioned and other embodiments of the present disclosure, a photoresist supply system includes a photoresist supply unit in which a photoresist container storing photoresist is stored; a photoresist supply device configured to provide the photoresist from the photoresist container to a wafer; an overhead hoist transport (OHT) rail connected to a ceiling surface; and an OHT configured to move along the OHT rail, wherein the OHT is configured to bring the photoresist container into and out of the photoresist supply unit.

According to the aforementioned and other embodiments of the present disclosure, a photoresist supply system includes a photoresist supply unit in which a photoresist container is stored; a photoresist supply device including a buffer tank; a pipeline connecting the photoresist container and the buffer tank; and an overhead hoist transport (OHT) configured to move along an OHT rail, wherein the photoresist supply unit is arranged above the photoresist supply device, and the OHT is configured to bring the photoresist container into and out of the photoresist supply unit.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing exemplary embodiments thereof in detail with reference to the attached drawings, in which:

FIGS. 1 and 2 are drawings illustrating a photoresist supply system according to some example embodiments;

FIG. 3 is a drawing for explaining the operation of the photoresist supply system according to some example embodiments;

FIGS. 4 through 6 are drawings illustrating a photoresist carriage according to some example embodiments;

FIG. 7 is a drawing illustrating a photoresist supply unit according to some example embodiments;

FIGS. 8 through 10 are drawings illustrating a photoresist changer according to some example embodiments;

FIGS. 11 through 13 are drawings for explaining the operations of the photoresist carriage and photoresist changer according to some example embodiments;

FIGS. 14 through 16 are drawings for explaining the operation of the photoresist supply system according to some example embodiments;

FIG. 17 is a drawing illustrating a photoresist supply system according to some example embodiments;

FIG. 18 is a drawing illustrating a photoresist supply system according to some example embodiments; and

FIG. 19 is a drawing illustrating a photoresist storage unit depicted in FIGS. 1 and 2.

### DETAILED DESCRIPTION

Like reference characters refer to like elements throughout.

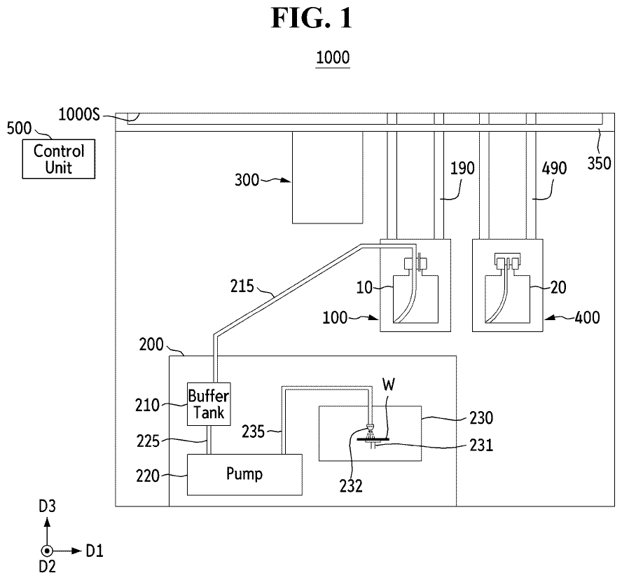

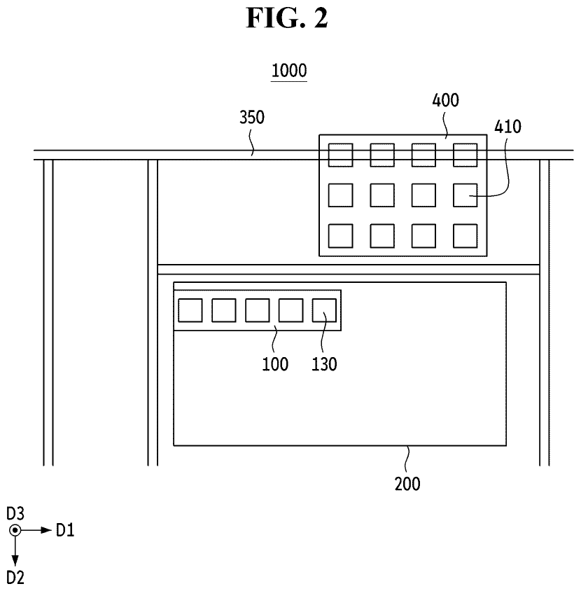

FIGS. 1 and 2 are diagrams illustrating a photoresist supply system according to some example embodiments.

Referring to FIGS. 1 and 2, a photoresist supply system 1000 may include a photoresist supply unit 100, a photoresist supply device 200, a first pipeline 215, an overhead hoist transfer (OHT) 300, an OHT rail 350, a photoresist storage unit 400, and a control unit 500.

A photoresist container 10 may be stored in the photoresist supply unit 100. Photoresist may be stored in the photoresist container 10. An inlet may be formed at the top of the photoresist container 10. The photoresist container 10 may be stored in the photoresist supply unit 100 with the inlet facing upward.

The photoresist supply device 200 may include a buffer tank 210, a pump 220, and a coating unit 230.

An inlet may be formed at the top of the buffer tank 210. The buffer tank 210 and the photoresist supply unit 100 may be connected by the first pipeline 215. The first pipeline 215 may connect the inlet at the top of the buffer tank 210 with the inlet at the top of the photoresist container 10. A valve for controlling the amount of photoresist flowing into the first pipeline 215 may be provided.

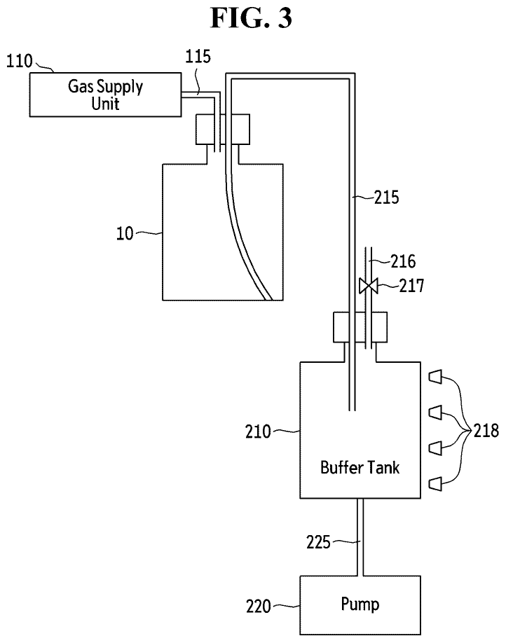

The buffer tank 210 may serve as a buffer for the photoresist flowing thereinto from the photoresist supply unit 100 through the first pipeline 215. The buffer tank 210 may temporarily store the photoresist supplied from the photoresist supply unit 100 through the first pipeline 215. Level sensors (e.g., level sensors 218 in FIG. 3) for detecting the level of the photoresist may be installed on one side of the buffer tank 210, and the photoresist may continuously be discharged into the buffer tank 210 until an appropriate level is reached. For example, photoresist may be continuously transferred from the photoresist supply unit 100 to the buffer tank 210 until level sensors installed on the buffer tank 210 detect that a desired level has been reached. When the photoresist container 10 in the photoresist supply unit 100 is replaced, the buffer tank 210 may provide the photoresist stored therein to prevent process interruptions.

The pump 220 and the buffer tank 210 may be connected by a second pipeline 225. The coating unit 230 and the pump 220 may be connected by a third pipeline 235. The photoresist stored in the buffer tank 210 may be supplied to the coating unit 230 via the third pipeline 235 by the pump 220. For example, the pump 220 may pump photoresist from the buffer tank 210 to the coating unit 230 via the third pipeline 235. A valve for controlling the amount of photoresist flowing into the second pipeline 225 may be provided.

A filter may be disposed in at least one of the second and third pipelines 225 and 235. The filter may filter particles and bubbles present in the photoresist.

A wafer W may be loaded onto a stage 231 arranged inside the coating unit 230. A discharge unit 232 may be connected to the third pipeline 235. The photoresist stored in the buffer tank 210 may be discharged into the discharge unit 232 via the third pipeline 235. A valve for controlling the amount of photoresist flowing into the third pipeline 235 may be provided. The photoresist supplied to the discharge unit 232 may be applied onto the wafer W loaded on the stage 231. A photoresist pattern may be formed on the wafer W using the photoresist.

The OHT rail 350 may be positioned on a ceiling surface 1000S of the photoresist supply system 1000. The OHT rail 350 may be connected to the ceiling surface 1000S. The OHT rail 350 may be arranged outside the photoresist supply device 200. The OHT rail 350 may be arranged above the photoresist supply device 200. The OHT rail 350 may have a straight shape, a curved shape, or a combination thereof.

The OHT 300 may be configured to move along the OHT rail 350. The OHT rail 350 may serve as the travel path for the OHT 300. The OHT 300 may be configured to transport photoresist containers 10 and 20. The OHT 300 may be configured to move between the photoresist supply unit 100 and the photoresist storage unit 400. The OHT 300 may be configured to transport the photoresist containers 10 and 20 between the photoresist supply unit 100 and the photoresist storage unit 400. The OHT 300 may be configured to bring the photoresist container 10 into or out of the photoresist supply unit 100. The OHT 300 may be configured to bring the photoresist container 20 into or out of the photoresist storage unit 400.

The photoresist storage unit 400 may be arranged outside the photoresist supply device 200. The photoresist storage unit 400 may be positioned on the ceiling surface 1000S. The photoresist storage unit 400 may be connected to the ceiling surface 1000S by a second connector 490.

Photoresist carriages 410 may be stored in the photoresist storage unit 400. The photoresist container 20 may be stored inside each of the photoresist carriages 410. Photoresist may be stored in the photoresist container 20. An inlet may be formed at the top of the photoresist container 20. The photoresist container 20 may be stored in the photoresist storage unit 400 with the inlet facing upward. For example, the photoresist storage unit 400 may store a plurality of photoresist carriages 410, and each of the photoresist carriages 410 may store one photoresist container 20 with the inlet of the photoresist container 20 facing upward.

For example, the photoresist carriages 410 may be arranged in the photoresist storage unit 400 in a first direction D1 and a second direction D2. The first and second directions D1 and D2 may be perpendicular to each other. The first and second directions D1 and D2 may be referred to as horizontal directions.

The control unit 500 may comprehensively control the photoresist supply system 1000. For example, the control unit 500 may control the operations of the photoresist supply unit 100, the photoresist supply device 200, the OHT 300, and the photoresist storage unit 400.

The control unit 500 may store and manage information regarding the photoresist container 10 stored in the photoresist supply unit 100 and the photoresist container 20 stored in the photoresist storage unit 400. For example, the control unit 500 may store information regarding the locations and quantities of the photoresist containers 10 and 20 in the photoresist supply unit 100 and the photoresist storage unit 400, respectively.

Barcodes or tags containing information regarding the photoresist stored in the photoresist containers 10 and 20 may be attached to the photoresist containers 10 and 20. Information regarding the photoresist stored in the photoresist containers 10 and 20 may be transmitted to the control unit 500 via the barcodes or tags.

The control unit 500 may be implemented as hardware, firmware, software, or a combination thereof. For example, the control unit 500 may be a computing device such as a workstation computer, desktop computer, laptop computer, or tablet computer. The control unit 500 may include a processor configured to perform predetermined computations and algorithms together with a memory device (such as a read-only memory (ROM) and a random-access memory (RAM)), such as a microprocessor, central processing unit (CPU), or graphics processing unit (GPU). The control unit 500 may also include a receiver and a transmitter for receiving and transmitting electrical signals. For example, the control unit 500 may be communicatively coupled with the photoresist supply unit 100, the photoresist supply device 200, the OHT 300, the photoresist storage unit 400, and any sensors (e.g., level sensors 218), and may send and receive data and/or instructions to and/or from each of the photoresist supply unit 100, the photoresist supply device 200, the OHT 300, the photoresist storage unit 400, and any sensors (e.g., level sensors 218).

The photoresist supply unit 100 may be arranged outside the photoresist supply device 200. The photoresist supply unit 100 may be positioned above the photoresist supply device 200. For example, the photoresist supply unit 100 may occupy a higher gravitational position and be in an upper vertical position relative to the photoresist supply device 200. As discussed further below, the photoresist supply unit 100 may include a plurality of photoresist changers 130, and each of the photoresist changers 130 may store one photoresist container 10

In some embodiments, the photoresist supply unit 100 may be arranged on the upper surface of the photoresist supply device 200. The photoresist supply unit 100 may be spaced apart from the upper surface of the photoresist supply device 200. The photoresist supply unit 100 may overlap the photoresist supply device 200 in a third direction D3.

The third direction D3 may be perpendicular to the first and second directions D1 and D2 and may be referred to as a vertical direction.

In some embodiments, the photoresist supply unit 100 may be positioned on the ceiling surface 1000S. The photoresist supply unit 100 may be connected to the ceiling surface 1000S by a first connector 190.

FIG. 3 is a diagram for explaining the operation of a photoresist supply system according to some example embodiments.

Referring to FIG. 3, the photoresist supply unit 100 in FIGS. 1 and 2 may further include a gas supply unit 110 and a gas supply pipeline 115.

The photoresist container 10 and the gas supply unit 110 may be connected by the gas supply pipeline 115.

A first drain pipeline 216 may be connected to the buffer tank 210. A valve 217 may be provided on the first drain pipeline 216.

The level sensors 218 may be provided on the buffer tank 210. The level sensors 218 may measure the level of photoresist in the buffer tank 210. A plurality of level sensors 218 may be arranged on the buffer tank 210. The number and positions of level sensors 218 are not particularly limited.

When gas (e.g., nitrogen) is supplied to the photoresist container 10 through the gas supply unit 110 and the valve 217 is opened, photoresist may be discharged from the photoresist container 10 to the buffer tank 210 through the first pipeline 215 due to the pressure of the gas. When photoresist is detected in the first pipeline 215, the gas supply from the gas supply unit 110 may be stopped. The photoresist in the first pipeline 215 may be detected by a sensor provided in the first pipeline 215. When photoresist is detected in the buffer tank 210, the valve 217 may be closed. The amount of photoresist in the buffer tank 210 may be detected by the level sensors 218.

The bottom of the photoresist container 10 is positioned higher than the top of the buffer tank 210. When photoresist is moved through the first pipeline 215 to a position lower than the bottom of the photoresist container 10, a siphon effect may occur. Even if the gas supply to the photoresist container 10 is stopped, photoresist may still be discharged into the buffer tank 210 due to the siphon effect.

When gas is supplied to the photoresist container 10 to discharge photoresist from the photoresist container 10 to the buffer tank 210, the longer the gas is supplied, the higher the likelihood of bubble formation in the photoresist and the risk of damage to the photoresist container 10. However, the photoresist supply system 1000 supplies photoresist to the buffer tank 210 using the siphon effect, thereby reducing the duration of the gas supply to the photoresist container 10 and preventing and/or reducing bubble formation in the photoresist and the risk of damage to the photoresist container 10.

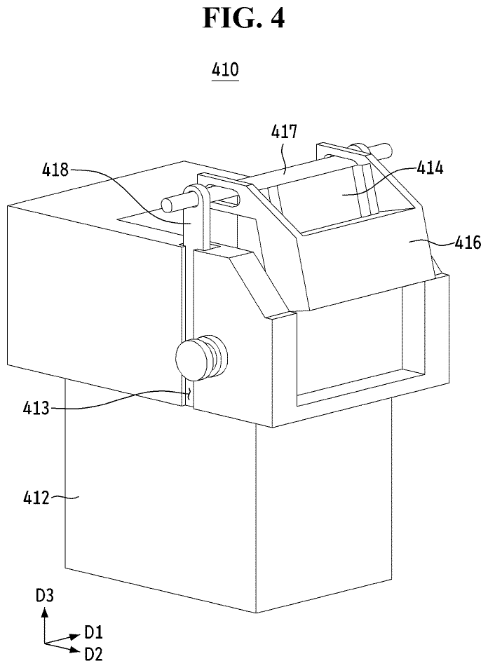

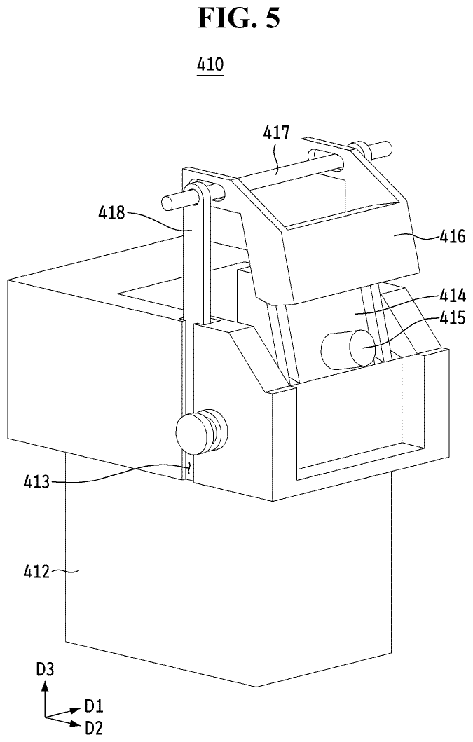

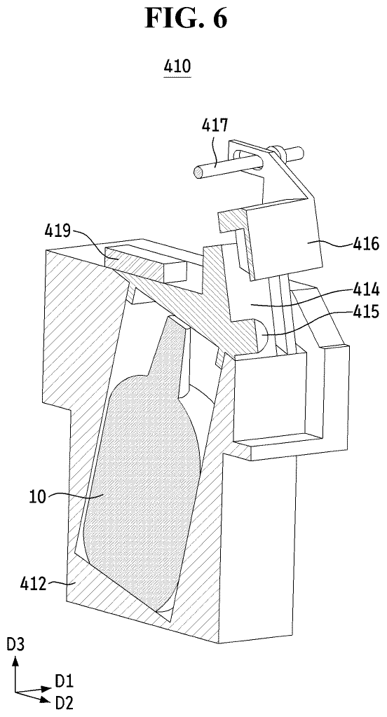

FIGS. 4 through 6 are diagrams illustrating a photoresist carriage according to some example embodiments. FIG. 4 is a diagram illustrating the locked state of the photoresist carriage according to some example embodiments. FIG. 5 is a diagram illustrating the unlocked state of the photoresist carriage according to some example embodiments. FIG. 6 is a cross-sectional view of the photoresist carriage according to some example embodiments, taken along the second direction D2. An OHT holder in FIG. 6 is omitted from FIGS. 4 and 5.

Referring to FIGS. 4 through 6, a photoresist carriage 410 may include a carriage body 412, grooves 413, a carriage cap 414, a carriage valve 415, an end cap 416, a first support 417, second supports 418, and an OHT holder 419.

A photoresist container 10 may be stored inside the carriage body 412. The internal space of the carriage body 412 may accommodate the photoresist container 10. The photoresist container 10 may be secured by the carriage body 412.

The grooves 413 may be formed on the upper parts of the sidewalls of the carriage body 412 in the first direction D1. The grooves 413 may extend lengthwise in the third direction D3.

The carriage cap 414 may cover the carriage body 412. The carriage cap 414 may cover the inlet of the photoresist container 10. The carriage cap 414 may include a carriage valve 415 protruding from the carriage cap 414. The carriage valve 415 may be connected to the inlet of the photoresist container 10.

The end cap 416 may be connected to the first support 417 extending in the first direction D1. The first support 417 may be connected to the second supports 418 extending in the third direction D3. The second supports 418 may be spaced apart in the first direction D1. The second supports 418 may be arranged on either side surface (e.g., side surfaces in the first direction D1) of the carriage body 412. The first support 417 may be connected to two second supports 418. The second supports 418 may be slidably coupled to the grooves 413 of the carriage body 412. As the second supports 418 move in the third direction D3 along the grooves 413, the end cap 416 may move in the third direction D3.

The end cap 416 may be positioned on the carriage cap 414. The end cap 416 may cover the carriage cap 414. As the end cap 416 moves in the third direction D3, the carriage cap 414 may be exposed or covered. When the second supports 418 move downward, the end cap 416 may move downward to cover the carriage cap 414. The end cap 416 may cover and protect the carriage valve 415. When the second supports 418 move upward, the end cap 416 may move upward to expose the carriage cap 414. The carriage valve 415 may be exposed by the end cap 416.

Referring to FIG. 4, the locked state of the photoresist carriage 410 may indicate a state where the carriage valve 415 is covered by the end cap 416. Referring to FIG. 5, the unlocked state of the photoresist carriage 410 may indicate a state where the carriage valve 415 is exposed by the end cap 416.

The OHT holder 419 may be positioned on the carriage body 412 and the end cap 416. The OHT holder 419 may be coupled to the carriage body 412 and the end cap 416. The OHT 300 may grip the OHT holder 419. The photoresist carriage 410 may be moved by the OHT 300 coupled to the OHT holder 419.

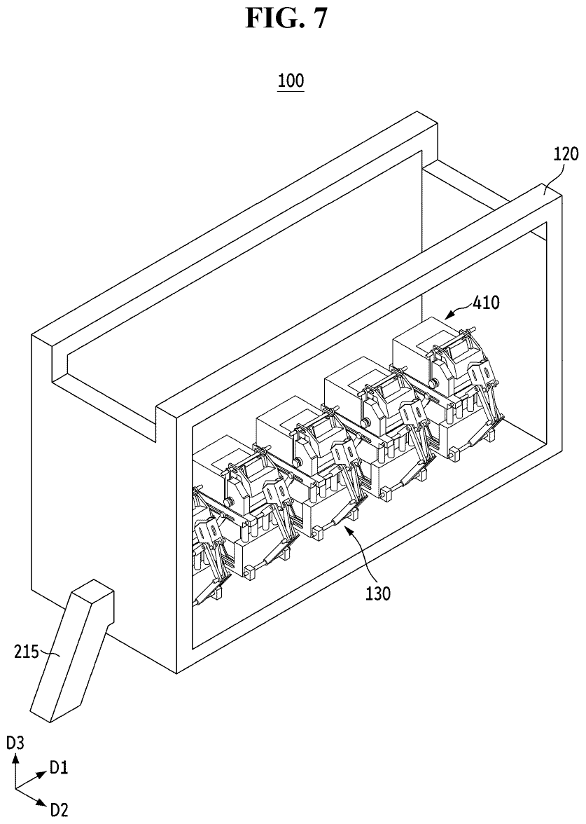

FIG. 7 is a diagram illustrating a photoresist supply unit according to some example embodiments.

Referring to FIG. 7, the photoresist supply unit 100 may extend in the first direction D1. The photoresist supply unit 100 may include a frame 120 and photoresist changers 130.

In some embodiments, the frame 120 may be connected to the ceiling surface 1000S (in FIG. 1) by the first connector 190 (in FIG. 1).

The photoresist changers 130 may be positioned on the lower part of the frame 120. The photoresist changers 130 may, for example, be arranged in the first direction D1. The number of photoresist changers 130 is not particularly limited. The photoresist changers 130 may be connected to the first pipeline 215.

Photoresist carriages 410 may be positioned on the photoresist changers 130. The photoresist carriages 410 may be seated inside the photoresist changers 130.

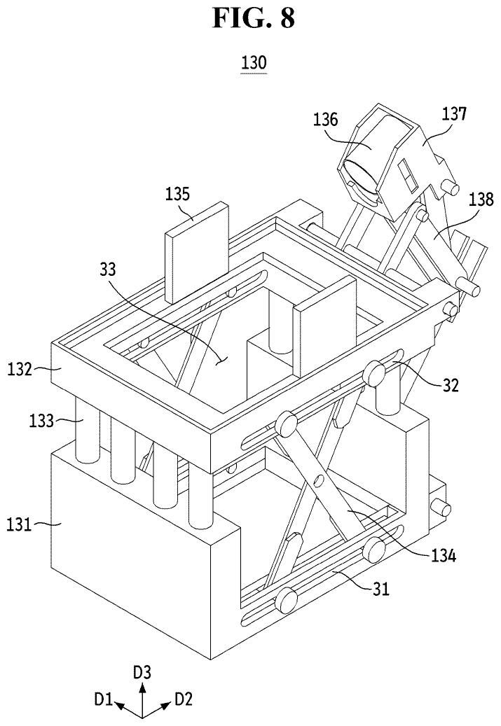

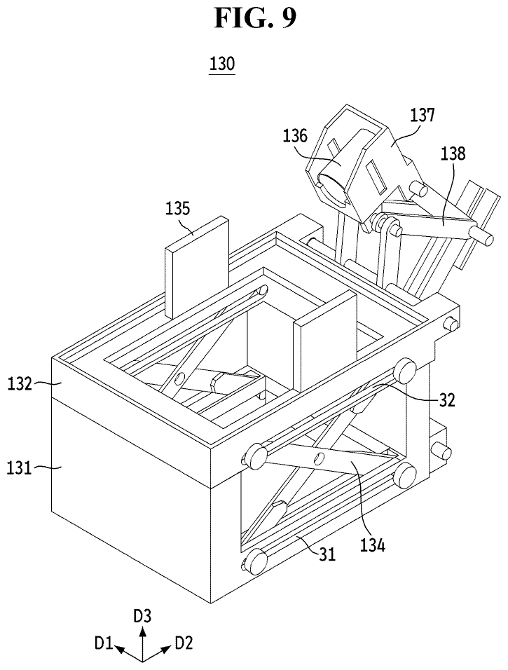

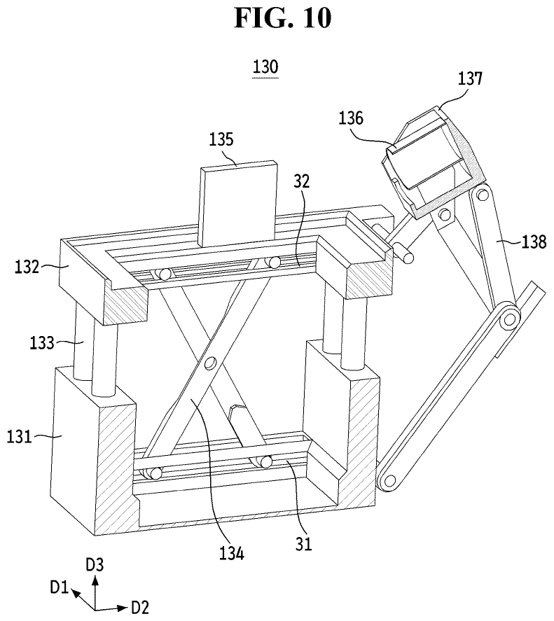

FIGS. 8 through 10 are diagrams illustrating a photoresist changer according to some example embodiments. FIG. 8 illustrates a disengaged state of the photoresist changer according to some example embodiments. FIG. 9 illustrates a connected state of the photoresist changer. FIG. 10 is a cross-sectional view of the photoresist changer according to some example embodiments, taken along the second direction D2.

Referring to FIGS. 8 through 10, a photoresist changer 130 may include a lower body portion 131, an upper body portion 132, first body connectors 133, second body connectors 134, end cap opening/closing pins 135, a photoresist cap 136, a cap holder 137, and a changer arm 138.

First openings 31 may be formed on either sidewall of the lower body portion 131 in the first direction D1. The first openings 31 may extend lengthwise in the second direction D2.

The upper body portion 132 may be arranged on the lower body portion 131. Second openings 32 may be formed on either sidewall of the upper body portion 132 in the first direction D1. The second openings 32 may extend lengthwise in the second direction D2.

The first body connectors 133 and the second body connectors 134 may be positioned between the lower and upper body portions 131 and 132. The lower and upper body portions 131 and 132 may be connected by the first body connectors 133 and the second body connectors 134.

The first body connectors 133 may be positioned between the sidewalls of the lower body portion 131 and the sidewalls of the upper body portion 132 in the second direction D2. The first body connectors 133 may be coupled to both the lower and upper body portions 131 and 132. Between sidewalls, in the second direction D2, of the lower and upper body portions 131 and 132, the first body connectors 133 may be aligned in the first direction D1. The first body connectors 133 may have a columnar shape extending in the third direction D3. The first body connectors 133 may move in the third direction D3 along grooves in the lower body portion 131.

The second body connectors 134 may be positioned between the sidewalls of the lower body portion 131 and the sidewalls of the upper body portion 132 in the first direction D1. The second body connectors 134 may be coupled to both the lower and upper body portions 131 and 132. From a planar perspective including the second and third directions D2 and D3, the second body connectors 134 may have an “X” shape. The second body connectors 134 may be coupled to the first openings 31 and the second openings 32. The second body connector 134 may move along the first openings 31 and the second openings 32.

As the first body connectors 133 move in the third direction D3 and the second body connectors 134 move along the first openings 31 and the second openings 32, the upper body portion 132 may move in the third direction D3. The first body connectors 133 and the second body connectors 134 may be configured to move the upper body portion 132 in the third direction D3.

The end cap opening/closing pins 135 may be arranged on the upper body portion 132. The end cap opening/closing pins 135 may protrude upward from the upper body portion 132. The upper body portion 132 may include a third opening 33 that extends through the interior of the upper body portion 132 in the third direction D3. The end cap opening/closing pin 135 may be spaced apart in the first direction D1 across the third opening 33.

The photoresist cap 136 may be supported by the cap holder 137. The changer arm 138 may be coupled to the cap holder 137. The changer arm 138 may be positioned on sidewalls, in the second direction D2, of the lower and upper body portions 131 and 132. The changer arm 138 may be coupled to the lower and upper body portions 131 and 132.

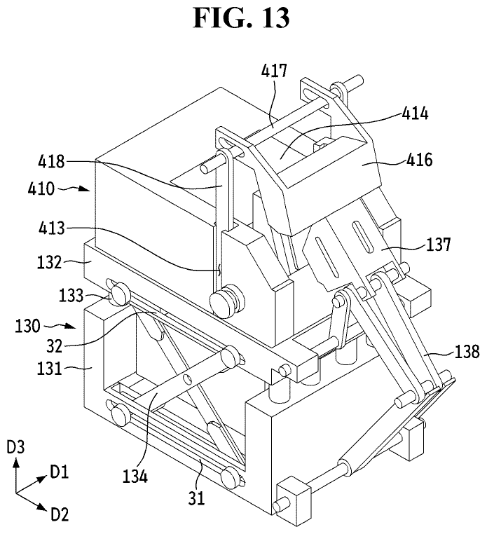

Referring to FIG. 8, the disengaged state of the photoresist changer 130 may indicate a state where the photoresist changer 130 is not coupled with a photoresist carriage 410. The photoresist changer 130 may be in a state with a relatively large height in the third direction D3. Referring to FIG. 9, the connected state of the photoresist changer 130 may indicate a state where the photoresist changer 130 is coupled with a photoresist carriage 410, as illustrated in FIG. 13. The photoresist changer 130 may be in a state with a relatively small height in the third direction D3.

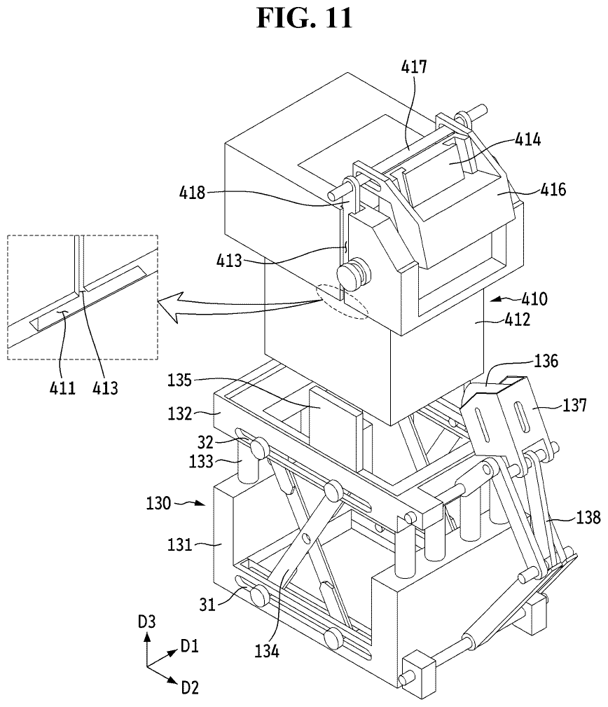

FIGS. 11 through 13 are diagrams for explaining the operations of the photoresist carriage and the photoresist changer according to some example embodiments.

Referring to FIG. 11, the photoresist carriage 410 may be positioned on the photoresist changer 130. The photoresist carriage 410 may be arranged on the third opening 33 of the upper body portion 132 of the photoresist changer 130. The photoresist carriage 410 may be in a locked state, and the photoresist changer 130 may be in an unlocked state.

Grooves 411 communicating with the grooves 413 may be formed in the carriage body 412 of the photoresist carriage 410. The grooves 411 may be formed on either sidewall of the carriage body 412 in the first direction D1. The grooves 411 may be positioned below the grooves 413. The grooves 411 may serve as a space for accommodating the end cap opening/closing pins 135 and may have a size corresponding to the end cap opening/closing pins 135.

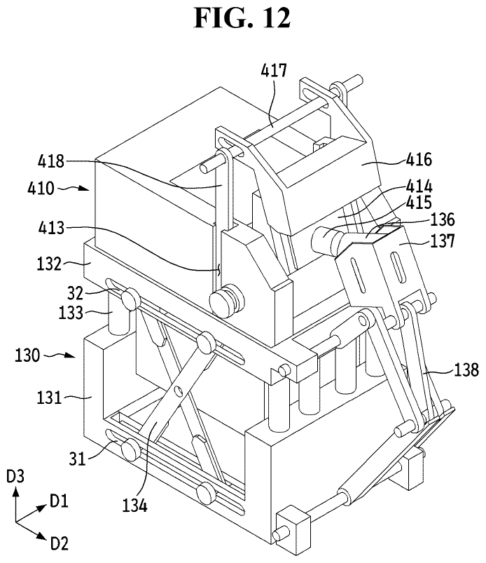

Referring to FIG. 12, the photoresist carriage 410 may be received into the photoresist changer 130. The end cap opening/closing pins 135 may be accommodated in the grooves 411.

As the photoresist carriage 410 is received into the photoresist changer 130, the end cap opening/closing pins 135 accommodated in the grooves 411 may push the second supports 418 in the third direction D3. Accordingly, the second supports 418 and the end cap 416 may move in the third direction D3, exposing the carriage valve 415. In other words, the photoresist carriage 410 may enter a disengaged state.

Referring to FIGS. 12 and 13, the photoresist carriage 410 may be seated in the photoresist changer 130. The lower body portion 131 and the upper body portion 132 may receive the photoresist carriage 410. As the photoresist carriage 410 is seated in the photoresist changer 130, the first body connectors 133 may be received into the lower body portion 131 along the grooves of the lower body portion 131, and the second body connectors 134 may move in the third direction D3, thereby lowering the height of the photoresist changer 130. In other words, the photoresist changer 130 may enter a connected state.

The carriage valve 415 of the photoresist carriage 410 may be coupled with the photoresist cap 136 of the photoresist changer 130. The photoresist cap 136 may be connected to the first pipeline 215 (in FIG. 7). The photoresist container 10 in the photoresist carriage 410 may be connected to the first pipeline 215 via the carriage valve 415 and the photoresist cap 136.

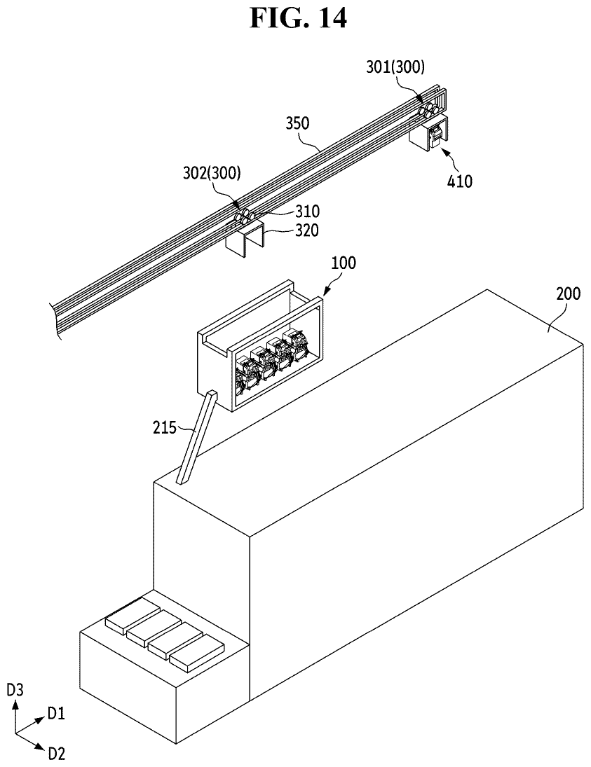

FIGS. 14 through 16 are diagrams illustrating the operation of the photoresist supply system according to some example embodiments.

Referring to FIG. 14, OHTs 300 may each include an OHT rail connection unit 310 and an OHT main body 320. The OHT rail connection unit 310 may be connected to the OHT main body 320. The OHT rail connection unit 310 may be connected to the top of the OHT main body 320. The OHT rail connection unit 310 may be fastened to the OHT rail 350. Using the OHT rail connection unit 310, the OHTs 300 may each travel along the OHT rail 350.

The OHTs 300 may be configured to transport photoresist carriages 410. Each of the OHTs 300 may further include an OHT hand capable of gripping the photoresist carriages 410. The OHT hands of the OHTs 300 may be positioned inside the OHT main bodies 320 of the OHTs 300 and may grip the OHT holders 419 of the photoresist carriages 410. The OHTs 300 may pick up the photoresist carriages 410 using the OHT hands. The photoresist carriages 410 may be housed within the OHT main bodies 320.

For example, the OHTs 300 may include a first OHT 301 and a second OHT 302. The number of OHTs 300 is not limited to what is illustrated.

When the photoresist in the photoresist carriage 410 within the photoresist supply unit 100 is depleted, the first OHT 301 may pick up a photoresist carriage 410 stored in the photoresist storage unit 400 of FIGS. 1 and 2. The first OHT 301 may pick up a photoresist carriage 410 containing the same type of photoresist as the depleted photoresist. After picking up the photoresist carriage 410 from the photoresist storage unit 400, the first OHT 301 may move to the photoresist supply unit 100.

The second OHT 302 may move to the photoresist supply unit 100. The second OHT 302 may be positioned on the photoresist carriage 410 in the photoresist supply unit 100 where the photoresist is depleted.

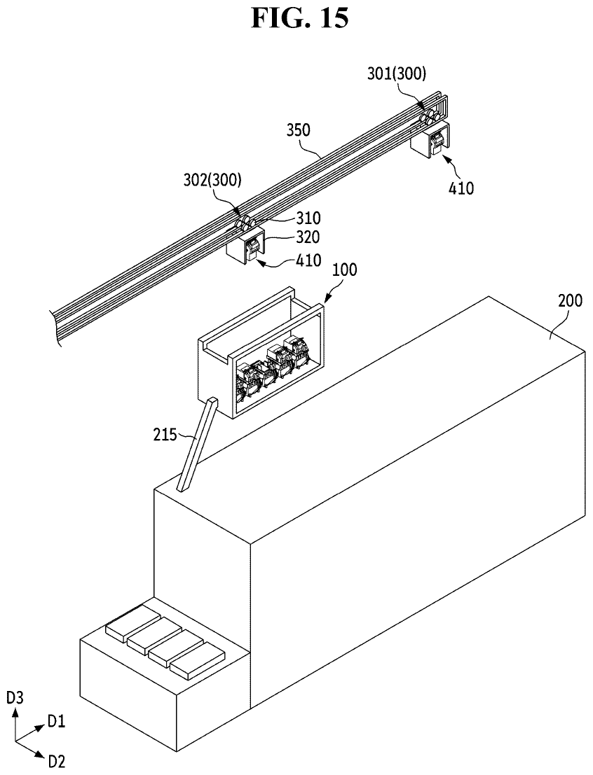

Referring to FIGS. 14 and 15, the second OHT 302 may pick up the photoresist carriage 410 in the depleted photoresist supply unit 100. The depleted photoresist supply unit 100 may be retrieved from the photoresist supply unit 100 by the second OHT 302. The first OHT 301 may move to the photoresist supply unit 100.

In some embodiments, the second OHT 302, which has retrieved the depleted photoresist supply unit 100 from the photoresist supply unit 100, may move to the photoresist storage unit 400 of FIGS. 1 and 2. The depleted photoresist carriage 410 may be stored in the photoresist storage unit 400.

In some other embodiments, the second OHT 302, which has retrieved the depleted photoresist carriage 410 from the photoresist supply unit 100, may move to an external storage outside the photoresist supply device 200, instead of moving to the photoresist storage unit 400. The depleted photoresist carriage 410 may be stored in the external storage.

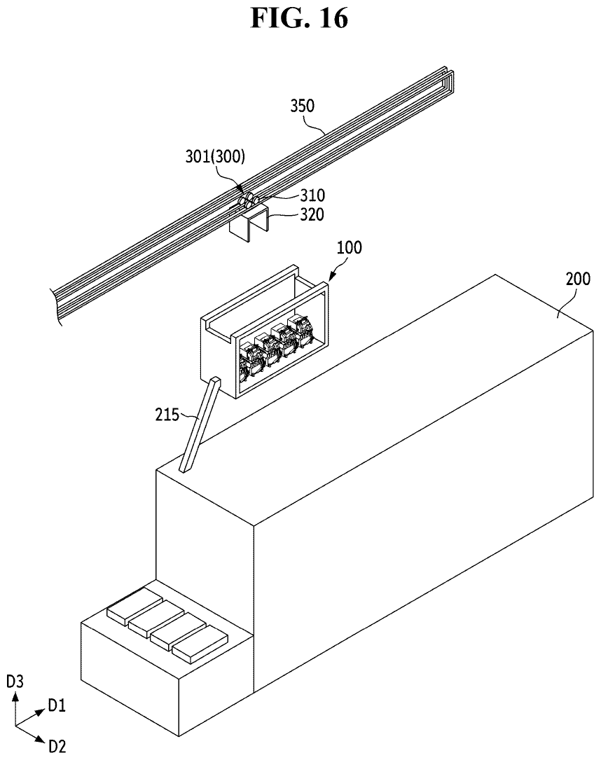

Referring to FIGS. 15 and 16, the first OHT 301 may deliver a photoresist carriage 410 to the photoresist supply unit 100. The first OHT 301 may provide a photoresist carriage 410, picked up from the photoresist storage unit 400, to the position where the depleted photoresist carriage 410 has been removed. The photoresist carriage 410 may be connected to a photoresist changer 130, and the photoresist may be supplied to the photoresist supply device.

Accordingly, the photoresist supply system 1000 may automatically return the depleted photoresist carriage 410 and replace it with a new photoresist carriage 410 using the OHTs 300.

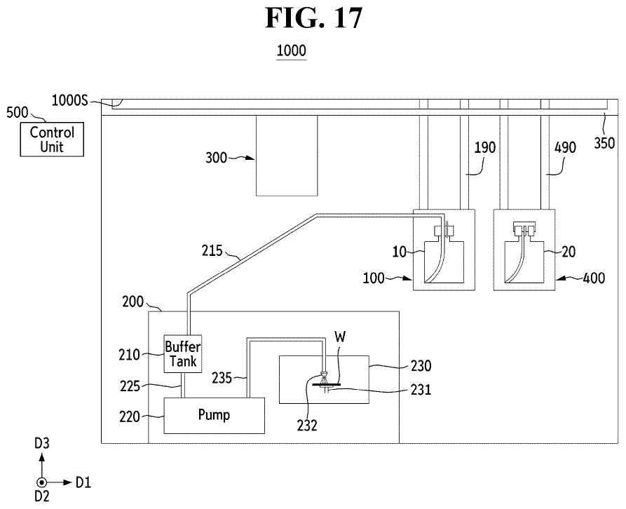

FIG. 17 is a diagram illustrating a photoresist supply system according to some example embodiments. For convenience of explanation, differences from what has been described earlier with reference to FIGS. 1 through 16 will be highlighted.

Referring to a photoresist supply system 1000 of FIG. 17, a photoresist supply unit 100 may not overlap a photoresist supply device 200 in a third direction D3. The photoresist supply unit 100 may be positioned on one side of the photoresist supply device 200.

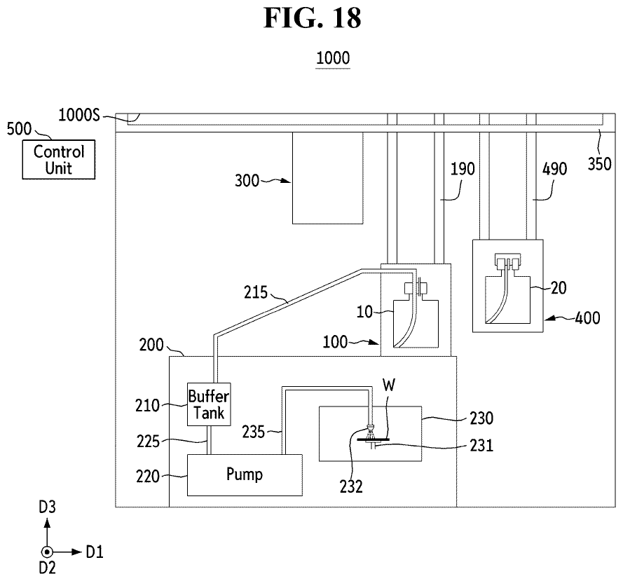

FIG. 18 is a diagram illustrating a photoresist supply system according to some example embodiments. For convenience of explanation, differences from what was described with reference to FIGS. 1 through 16 will be highlighted.

Referring to a photoresist supply system 1000 of FIG. 18, a photoresist supply unit 100 may be positioned on the upper surface of a photoresist supply device 200. The photoresist supply unit 100 and the photoresist supply device 200 may be integrated.

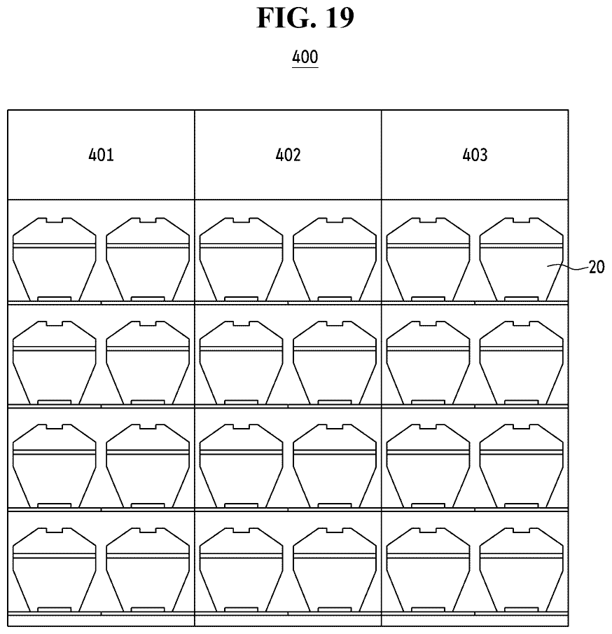

FIG. 19 is a diagram illustrating the photoresist storage unit of FIGS. 1 and 2.

Referring to FIG. 19, the photoresist storage unit 400 may store photoresist carriages 410 based on the characteristics of photoresist.

For example, the photoresist carriages 410 may be stored in the photoresist storage unit 400 depending on the temperature requirements for managing the photoresist. Photoresist carriages 410 containing photoresist requiring room temperature management may be stored in a first storage unit 401, photoresist carriages 410 containing photoresist requiring refrigeration or freezing management may be stored in a second storage unit 402, and photoresist carriages 410 containing photoresist requiring chemical management may be stored in a third storage unit 403.

The photoresist carriages 410 stored in each of the first and second storage units 401 and 402 may allow for temperature control.

For example, the first, second, and third storage units 401, 402, and 403 may have different colors. In another example, the photoresist carriages 410 stored in the first storage unit 401, the photoresist carriages 410 stored in the second storage unit 402, and the photoresist carriages 410 stored in the third storage unit 403 may have different colors.

The number of storage units included in the photoresist storage unit 400 and the criteria for classifying the storage units are not particularly limited.

While embodiments of the present disclosure have been described with reference to the accompanying figures, the present disclosure is not limited to these embodiments and may be implemented in various other forms. Those skilled in the art will understand that modifications can be made without departing from the spirit or essential features of the invention. Therefore, the embodiments described herein should be understood as illustrative and not restrictive in any way.

What is claimed is:

1. A photoresist supply system comprising:
a photoresist supply unit in which a photoresist container having an inlet at its top is stored;
a photoresist supply device including a buffer tank having an inlet at its top; and
a pipeline connecting the inlet of the photoresist container and the inlet of the buffer tank,
wherein the photoresist supply unit is positioned above the photoresist supply device.

2. The photoresist supply system of claim 1, wherein a lowermost part of the photoresist container is positioned above an uppermost part of the buffer tank.

3. The photoresist supply system of claim 1,
wherein the photoresist supply unit is connected to a ceiling surface, and
wherein the photoresist supply unit and the photoresist supply device overlap in a vertical direction.

4. The photoresist supply system of claim 1,
wherein the photoresist supply unit is connected to a ceiling surface, and
wherein the photoresist supply unit and the photoresist supply device do not overlap in a vertical direction.

5. The photoresist supply system of claim 1, wherein the photoresist supply unit is positioned on an upper surface of the photoresist supply device.

6. The photoresist supply system of claim 1,
wherein the photoresist supply unit is formed outside the photoresist supply device, and
wherein the photoresist supply unit does not overlap with the buffer tank in a vertical direction.

7. The photoresist supply system of claim 1, further comprising:
an overhead hoist transport (OHT) rail connected to a ceiling surface; and
an OHT configured to move along the OHT rail,
wherein the OHT is configured to bring the photoresist container into and out of the photoresist supply unit.

8. A photoresist supply system comprising:
a photoresist supply unit in which a photoresist container storing photoresist is stored;
a photoresist supply device configured to provide the photoresist from the photoresist container to a wafer;
an overhead hoist transport (OHT) rail connected to a ceiling surface; and
an OHT configured to move along the OHT rail,
wherein the OHT is configured to bring the photoresist container into and out of the photoresist supply unit.

9. The photoresist supply system of claim 8,
wherein the OHT is configured to transport a photoresist carriage, and
wherein the photoresist carriage includes:
a carriage body in which the photoresist container is stored;
a carriage cap configured to cover the photoresist container and connected with the photoresist container;
a first support extending in a horizontal direction;
second supports coupled to the first support and extending in a vertical direction on either side surface of the carriage body; and
an end cap coupled to the first support and covering the carriage cap.

10. The photoresist supply system of claim 9,
wherein the photoresist supply unit includes:
an upper body portion and a lower body portion configured to accommodate the photoresist carriage;
end cap opening/closing pins protruding in the vertical direction from the upper body portion and configured to push the second supports of the photoresist carriage accommodated in the upper and lower body portions, in the vertical direction; and
a photoresist changer coupled to the upper and lower body portions and including a photoresist cap connected with the carriage cap, and
wherein the OHT is configured to bring the photoresist carriage into and out of the photoresist changer.

11. The photoresist supply system of claim 10, wherein the photoresist changer further includes a body connector configured to connect the upper and lower body portions and to move the upper body portion in the vertical direction.

12. The photoresist supply system of claim 8, further comprising:
a photoresist storage unit connected to the ceiling surface and configured to store the photoresist container brought into and out of the photoresist supply unit,
wherein the OHT is configured to transport the photoresist container between the photoresist supply unit and the photoresist storage unit.

13. The photoresist supply system of claim 12,
wherein the photoresist storage unit stores a photoresist carriage,
wherein the photoresist carriage includes:
a carriage body in which the photoresist container is stored; and
a carriage cap connected to an inlet of the photoresist container, on the carriage body, and
wherein the OHT is configured to transport the photoresist carriage.

14. The photoresist supply system of claim 12, wherein the photoresist storage unit includes:
a first storage unit configured to store the photoresist container at room temperature; and
a second storage unit configured to refrigerate or freeze the photoresist container.

15. The photoresist supply system of claim 8, wherein the photoresist supply unit is connected to the ceiling surface and arranged above the photoresist supply device.

16. The photoresist supply system of claim 8, wherein the photoresist supply unit is arranged on an upper surface of the photoresist supply device.

17. A photoresist supply system comprising:
a photoresist supply unit in which a photoresist container is stored;
a photoresist supply device including a buffer tank;
a pipeline connecting the photoresist container and the buffer tank; and
an overhead hoist transport (OHT) configured to move along an OHT rail,
wherein the photoresist supply unit is arranged above the photoresist supply device, and
wherein the OHT is configured to bring the photoresist container into and out of the photoresist supply unit.

18. The photoresist supply system of claim 17, wherein a lowermost part of the photoresist container is positioned above an uppermost part of the buffer tank.

19. The photoresist supply system of claim 17,
wherein the OHT is configured to transport a photoresist carriage, and
wherein the photoresist carriage includes:
a carriage body in which the photoresist container is stored;
a carriage cap configured to cover the photoresist container and connected with the photoresist container;
a first support extending in a horizontal direction;
second supports coupled to the first support and extending in a vertical direction on either side surface of the carriage body; and
an end cap coupled to the first support and covering the carriage cap.

20. The photoresist supply system of claim 19,
wherein the photoresist supply unit includes:
an upper body portion and a lower body portion configured to accommodate the photoresist carriage;
end cap opening/closing pins protruding vertically from the upper body portion and configured to push the second supports of the photoresist carriage accommodated in the upper and lower body portions in the vertical direction; and
a photoresist cap coupled to the upper and lower body portions and connected with the carriage cap, and
wherein the OHT is configured to bring the photoresist carriage into and out of a photoresist changer.
